(19) United States
(12) Patent Application Publication
(10) Pub. No.: US 2004/0136224 A1
(43) Pub. Date: Jul. 15, 2004

(54) One button external backup

(76) Inventors: John Hamer, Cupertino, CA (US); James McGrath, Mountain View, CA (US); Patrick Weiher, Los Altos, CA (US); James Lin, San Jose, CA (US); Michael Webster, San Jose, CA (US)

Correspondence Address: HANSRA PATENT SERVICES, 4525 GLEN MEADOWS PLACE, BELLINGHAM, WA, 98226, US

(21) Appl. No.: 10/656,896

(22) Filed: Sep. 5, 2003

Related U.S. Application Data
(60) Provisional application No. 60/408,690, filed on Sep. 6, 2002.

(51) Int. Cl. G11C 11/22

(52) U.S. Cl. 365/145

(57) ABSTRACT

A, preferably external, storage device is provided with a button or other user input which, when activated, causes a launch of an application such as a backup of data from the host device onto the external storage device. Preferably, the external storage device includes a hard disk drive. Communication with the host device can be made using USB, IEEE 1394, Ethernet, wireless links or other links. The external device is configured to allow the host to become aware of a button press, e.g., by a notification or interrupt technique, or by a polling technique.

### CROSS-REFERENCE TO RELATED APPLICATIONS

The present application claims priority based on U.S. Provisional Patent Application Serial No. 60/408,690 filed Sep. 6, 2002 titled “One Touch Backup For Storage Devices” (Attorney File No. 3123-514-prov), the entirety of which is incorporated herein by reference.

### TECHNICAL FIELD

The present invention is directed to a method and apparatus which can simplify the launching of a computer application and preferably which can launch a backup application, or other applications, with a reduced number of steps or actions such as by pressing a single button, preferably mounted on, or otherwise associated with, an external disk drive or other external storage device.

### BACKGROUND INFORMATION

Experienced computer users generally recognize that launching a computer application typically requires several steps or actions. For example, even when a single mouse click suffices to launch an application, the process generally involves locating the mouse (which may be non-trivial when a mouse is located among or under desk clutter and the like), moving the mouse and coordinating such movement with movement of a cursor on a screen, while visually locating a desired icon (assuming the icon is already on the screen, which is not always the case), then clicking the correct mouse button. Although a single click launch is not unknown, very often an initial click must be followed by other selections such as choosing options, confirming choices and the like.

Although mouse launches are believed to be the most common, it is often possible to perform launches using only keys of a keyboard. Similarly, other non-storage devices such as scanners can launch applications on a host device. Although keyboard launches typically involve a key combination or otherwise involve multiple actions, even a single key launch (such as in the case of programmable macro keys or key combinations in word processors and the like) could involve multiple steps including, e.g., finding a keyboard among or under clutter, remembering the key or key combination for the desired function, and not uncommonly, selecting additional options or confirming choices and the like. Such multiple-step launches are believed not only to consume an undesirable amount of time, to perform the multiple steps, but also involve a sustained shift in focus away from other work that the user may be involved in. It is believed that such consumption of time and/or shift of focus may discourage some users from performing certain tasks such as routine or maintenance tasks including, for example, data backup. Accordingly, it would be useful to reduce the number of steps or actions and/or reduce the need for shifting of focus associated with the launching of an application, particularly a backup application.

Some computers provide for a timed or automated backup procedure. While such a procedure may have certain benefits, it is believed to also present certain difficulties which may make it advisable not to use an automated backup as the sole or main backup approach. If automated backup performs a backup procedure during normal working hours, such procedure may slow down or otherwise interfere with normal working operations and it may be difficult or impossible to backup data programs and the like which are being used in the foreground during such backup procedure. Scheduling of backups during nighttime or other non-work hours requires that a user remember to leave the computer running (or in sleep mode or the like) overnight. Leaving the computer in this mode can not only increase energy usage but may present security risks particularly when the computer is normally connected to a network or to the internet. Automated backup presents a particular issue with respect to laptop computers which may, routinely, be decoupled from the backup drive or other backup resource, at the time of the automatic backup. Accordingly, it would be useful to provide for backup other than, or in place of, automated or timed backups but, preferably, of a simplified nature so as not to discourage the performance of backups.

In at least some previous systems, two or more computers were functionally coupled permitting data to be copied from one computer to another. Examples include computers coupled on a local area network or coupled via the internet and systems in which one or more hand-held computers (such as a Palm Pilot® or other PDA (personal digital assistant)) is coupled to another computer. Although it might be physically possible to use such systems for data backup, it is believed substantially inefficient to do so since this means that adding a backup capability requires the expense of having an entire additional computer or at least means that one or more computers in a system have a substantial amount of storage capacity occupied by storing backup data as opposed to being used for ordinary, non-backup computing uses. Accordingly, it would be useful to provide a system in which a backup capability can be added to a system which previously had none, without requiring the addition of a new computer to the system and without the need to use up a substantial portion of the storage capacity of one of the computers in the system.

Moreover, it is believed useful to distinguish between data backup, which preserves a copy of desired files (e.g., in case the original file is corrupted) and synchronization, such as provided in programs like Microsoft® Briefcase, which is used to synchronize files, e.g., modified on a portable computer or PDA (personal digital assistant) with their counterparts on a main computer. For example, using Briefcase, when the portable computer is reconnected at the main computer, Briefcase can automatically update the files on the main computer to the modified versions. Such synchronization is a procedure which is significantly different from, for example, maintaining a second copy of selected files from a main computer, onto, e.g., an external storage device.

In the past, some backups were performed using so-called floppy disks, and, increasingly, backups are being performed using CD-R/W (compact disk-read/write) or WORM (write once/read many) optical disks. Although optical disks have large capacity compared to floppy disks, it is still generally necessary to use multiple disks in order to perform a full backup of a hard drive, or even a selected backup in many cases, particularly given the large size of many data files in the present context, such as video files, photograph files, graphics files, and even certain audio or text files. The need for multiple disks in the performance of the backup, generally means that, in a practical system, it is necessary to engage in a time-consuming and focus-shifting process of inserting and removing multiple disks, and accurately labeling each disk. Furthermore, such swapping of disks is often further slowed by a typical process wherein pushing the eject button on the CD drive causes the computer to perform time-consuming tasks such as completion of writing the files, closing certain applications and the like, before causing the disk to actually eject. Moreover, in the event it is necessary to recover data from a backup file, it is typically necessary to search through multiple disks to locate a disk with the desired data. Furthermore, the process of writing data onto a CD-R/W or WORM disk is relatively slow compared to, e.g., the time required to write corresponding amount of data onto a hard drive. Accordingly, it would be useful to provide a backup system which is not restricted to the time-consuming procedures and disk proliferation issues typically associated with optical disk backups.

Although it is possible to provide for backup to a hard drive which is internal to a computer (i.e., mounted in the main computer chassis or “CPU” box), this generally involves either forming a separate partition of a disk (which may reduce the effective main capacity of the disk) or mounting an additional disk drive in the chassis (which many users are reluctant to perform themselves). Such reluctance effectively multiplies the problem when there is a desire or need for expandability of a backup system (i.e., providing a second, third or more backup drives). In addition, the number of drives that can physically fit within the chassis, and can be connected to the computer electronically, may be limited. Additionally, once such disk drives have been mounted internally, it is relatively difficult and time consuming to remove such drives, so that it is generally infeasible to use an internal disk drive, for example, to store backup data off-site and/or store backup data overnight in a safe or other secure location. Accordingly, it would be useful to provide a backup system which can be implemented on a hard disk drive or drives while avoiding the need to partition disks or mount additional drives inside the computer chassis.

### SUMMARY

The present invention includes recognition and/or appreciation of the existence and/or nature of shortcomings or problems of previous approaches, including as described herein.

According to one aspect of the present invention, a user can initiate a backup with a reduced number of acts or steps (compared to at least some previous approaches) preferably by a single press of a single button. Preferably the button is mounted on or near, or otherwise associated with, a storage device. Preferably the storage device includes a hard disk drive and preferably the disk drive is mounted externally (with respect to the main chassis or CPU of the computer or other host device). In this way, a backup system can be provided in such a manner that backup consumes very little of a user's time and requires little, if any, shifting of focus away from other work or tasks being performed on the computer. When the button or other input device is mounted on or otherwise associated with an external disk drive, performance of routine backup will not be deterred by the hiding of a mouse or computer keyboard among or under desk clutter, and it is unlikely that a backup of data on a laptop or other disconnected computer will be aborted because the target disk drive (or similar backup device) is unavailable (since it is believed more likely a button mounted on an external drive will be pressed when the external drive is coupled to the laptop). Preferably, there is little or no requirement for additional confirmation or other actions and preferably there are either substantially no displays on the computer screen, or any such displays are preferably sized and positioned so as to provide little, if any, interference with other operations the user may be performing on the computer.

By providing at least some embodiments in which one-button backup is provided using an external storage device, it is possible to implement the present invention without requiring the CPU or main chassis of a computer to be opened. In one embodiment, the external device is coupled using such communication channels as a universal serial bus (USB) channel, an IEEE 1394 (Firewire) channel, an Ethernet channel, a wireless communication link and the like. Preferably, embodiments are provided which permit an external device to be connected and/or disconnected without having to shut down or reboot the computer (“hot swapping”) and in some embodiments, preferably providing for connecting multiple external units, e.g., by daisy-chaining or similar connection architectures.

Preferably, by providing embodiments in which storage or backup is made to a hard disk drive, backup can be performed in a relatively rapid fashion and without the need for inserting or using an undesirably large number of disks. Although it is possible to provide embodiments of the present invention in which a button on an external storage device is dedicated to a single function, such as data backup, it is also possible to provide embodiments in which there is substantial flexibility in use of the button (or other input device) such as by allowing for the user to select or program the function to be performed in response to a button push.

In at least one embodiment, a, preferably external, storage device is provided with a button or other user input which, when activated, causes a launch of an application such as a backup of data from the host device onto the external storage device. Preferably, the external storage device includes a hard disk drive. Communication with the host device can be made using USB, IEEE 1394 (Firewire), Ethernet, wireless links or other links. The external device is configured to allow the host to become aware of a button press, e.g., by a notification or interrupt technique, or by a polling technique.

### BRIEF DESCRIPTION OF THE DRAWINGS

FIG. 1 is a front perspective view of an external storage device according to an embodiment of the present invention;

FIG. 2 is a rear elevational view of an external storage device according to an embodiment of the present invention;

FIG. 3 is a front elevational view of an external storage device according to an embodiment of the present invention;

FIG. 4 is a top plan view of an external storage device according to an embodiment of the present invention;

FIG. 5 is a bottom plan view of an external storage device according to an embodiment of the present invention;

FIG. 6 is a right side elevational view of an external storage device according to an embodiment of the present invention, wherein the left side elevational view is substantially identical thereto;

FIG. 7 is a rear perspective view of an external storage device according to an embodiment of the present invention;

FIG. 8 is a block diagram of a computer system including an external disk drive, according to an embodiment of the present invention;

FIG. 9 is a flow chart of an installation procedure usable according to an embodiment of the present invention;

FIG. 10 is a flow chart of a procedure involving a launcher usable according to an embodiment of the present invention;

FIG. 11 is a flow chart of a button press procedure usable according to an embodiment of the present invention;

FIG. 12 is a flow chart of an interrupt-based procedure usable according to an embodiment of the present invention;

FIG. 13 is a flow chart of a polling-based procedure usable according to an embodiment of the present invention;

FIG. 14 is a diagram of an input information format that can be used in accordance with an embodiment of the present invention;

FIG. 15 is a top perspective view of an external storage device according to an embodiment of the present invention;

FIG. 16 is a top plan view of an external storage device according to an embodiment of the present invention;

FIG. 17 is a bottom plan view of an external storage device according to an embodiment of the present invention;

FIG. 18 is a front elevational view of an external storage device according to an embodiment of the present invention;

FIG. 19 is a rear elevational view of an external storage device according to an embodiment of the present invention, wherein broken lines are shown for illustrative purposes;

FIG. 20 is a right side elevational view of an external storage device according to an embodiment of the present invention, wherein broken lines are shown for illustrative purposes;

FIG. 21 is a left side elevational view of an external storage device according to an embodiment of the present invention, wherein broken lines are shown for illustrative purposes;

FIG. 22 is a front perspective view of an external storage device according to an embodiment of the present invention, wherein broken lines are shown for illustrative purposes;

FIG. 23 is a top plan view of an external storage device according to an embodiment of the present invention;

FIG. 24 is a bottom plan view of an external storage device according to an embodiment of the present invention, wherein broken lines are shown for illustrative purposes;

FIG. 25 is a front elevational view of an external storage device according to an embodiment of the present invention, wherein broken lines are shown for illustrative purposes;

FIG. 26 is a rear elevational view of an external storage device according to an embodiment of the present invention, wherein broken lines are shown for illustrative purposes;

FIG. 27 is a left side elevational view of an external storage device according to an embodiment of the present invention, wherein broken lines are shown for illustrative purposes; and,

FIG. 28 is a right side elevational view of an external storage device according to an embodiment of the present invention, wherein broken lines are shown for illustrative purposes.

### DETAILED DESCRIPTION OF THE PREFERRED EMBODIMENTS

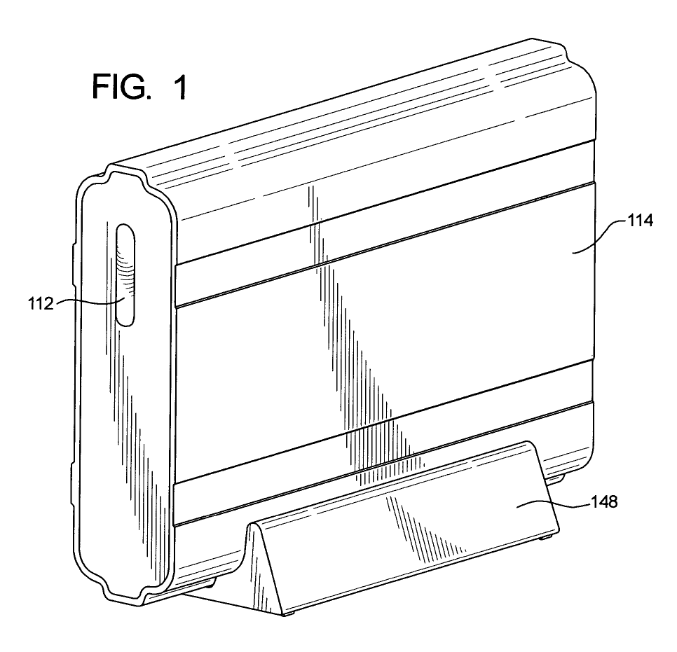

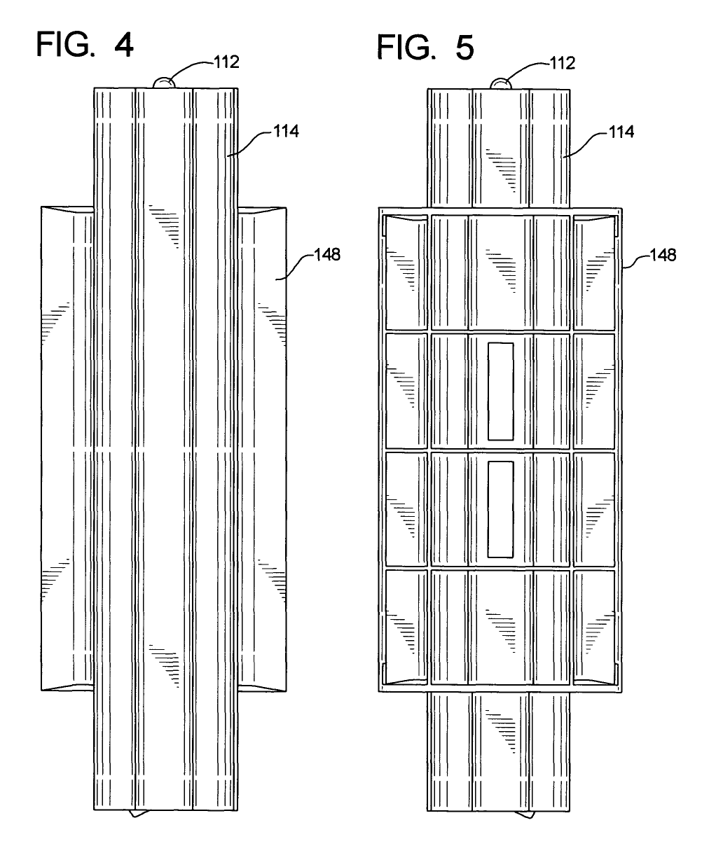

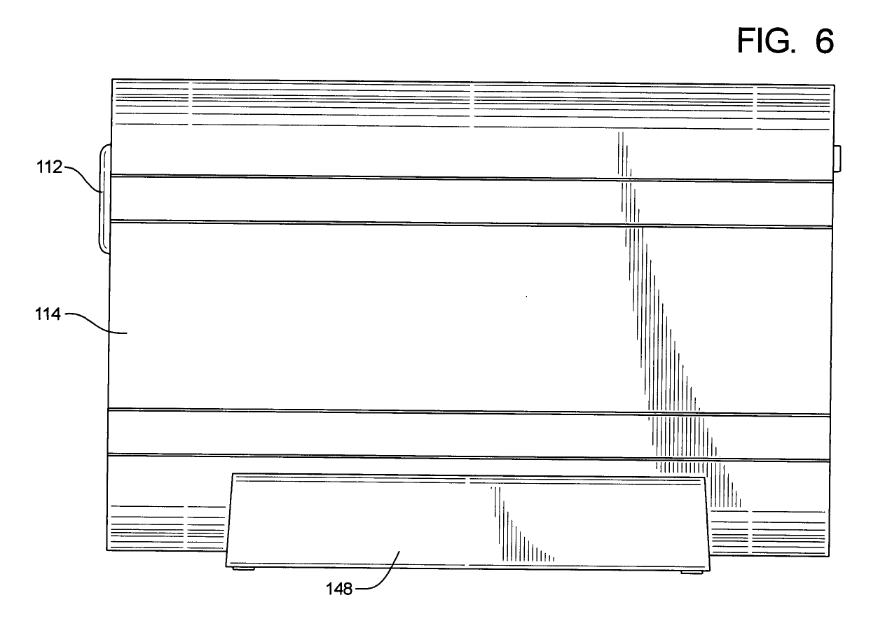

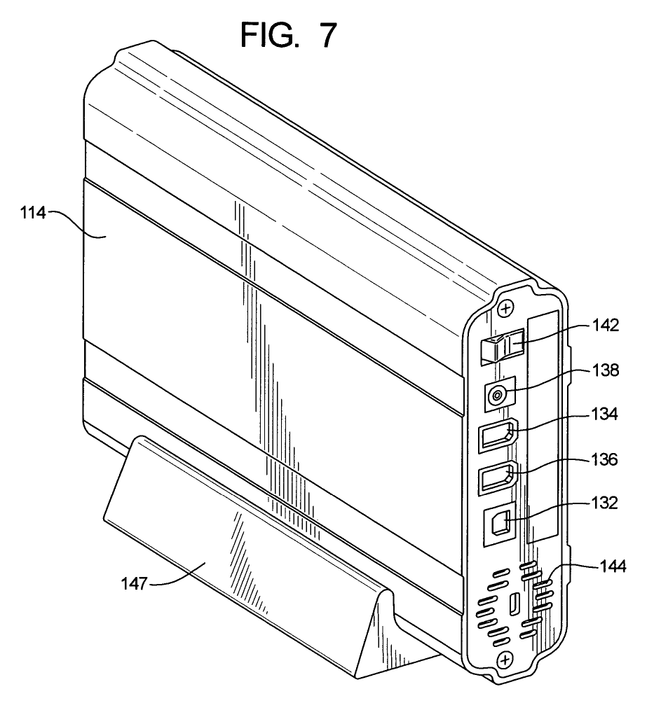

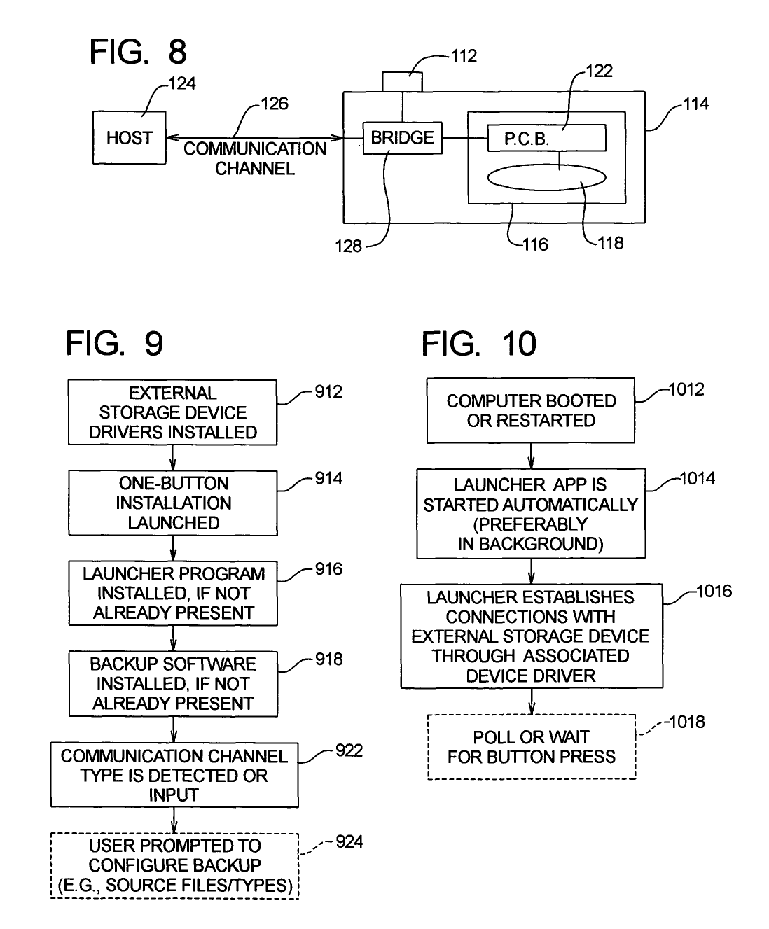

According to one embodiment of the present invention, a push button 112 (FIGS. 1-7), is associated with an external storage device such as an external disk drive 114 by being mounted thereon. As depicted in FIG. 8, according to one embodiment of the invention, the external disk drive 114 includes a hard disk drive 116 containing at least one rotatable disk 118 along with the typically-used actuator arms, controllers, or voice-coil motors or the like (not shown). Generally, a hard disk drive 116 is provided with a printed circuit board (PCB) 122 which contains some or all of the control normally used in reading data from, or writing data to, the disk 118. Those with skill in the art will understand how to make or obtain and use disk drives 116 in the present invention, at least after understanding the present disclosure. A number of disk drives can be used in connection with embodiments of the present invention. In one embodiment, the disk drive is a 7200-rpm drive including a cache buffer using an ultra ATA 133 interface, although other drives are anticipated. Those with skill in the art will understand how to implement embodiments of the present invention using this type of disk drive or other disk drives or data storage systems at least after understanding the present disclosure.

In the embodiment depicted in FIG. 8, the external disk drive 114 is coupled to a host 124 which may be, e.g., a personal computer or another preferably programmable device which stores data. The host 124 communicates with the external disk drive 114 via a communication channel 126 coupled through a bridge component or a circuit 128. In general, the bridge component or circuit 128 provides for translating data received over the communication channel 126 into a form usable by the disk drive 116 including, for example, translating serial to parallel data and the like. Typically, a bridge circuit 128 includes devices capable of performing or executing logical operations, and may include devices which can be controlled according to firmware (or software), such as a microprocessor, although bridge circuits may also contain other logic components such as gate arrays and/or applications-specific integrated circuits (ASICS) and the like. Those with skill in the art will understand how to use and/or program bridge chips or bridge chip components so as to implement embodiments of the present invention, at least after understanding the present disclosure. In particular, those with skill in the art will understand how to couple a button 112 to the bridge chip 128 and how to program bridge chip firmware to implement procedures according to the present invention, including procedures as described and depicted in FIGS. 9-13.

A number of communication channels 126 can be used in accordance with embodiments of the present invention including, for example, a USB (particularly USB 2.0 or higher) communication channel, an IEEE 1394 (Firewire) communications channel, an Ethernet communications channel, a wireless communications channel (such as so-called 802.11(b) or 802.11(g) communication channels) and the like. Preferably the communication channel is configured in such a manner that the external device is hot swappable and also is preferably provided in such a manner that the presence and nature of the external device can be automatically recognized (using technology such as plug and play™ and the like). Those with skill in the art will understand how to implement embodiments of the present invention so as to provide hot swapability and/or plug and play™ at least after understanding the present disclosure.

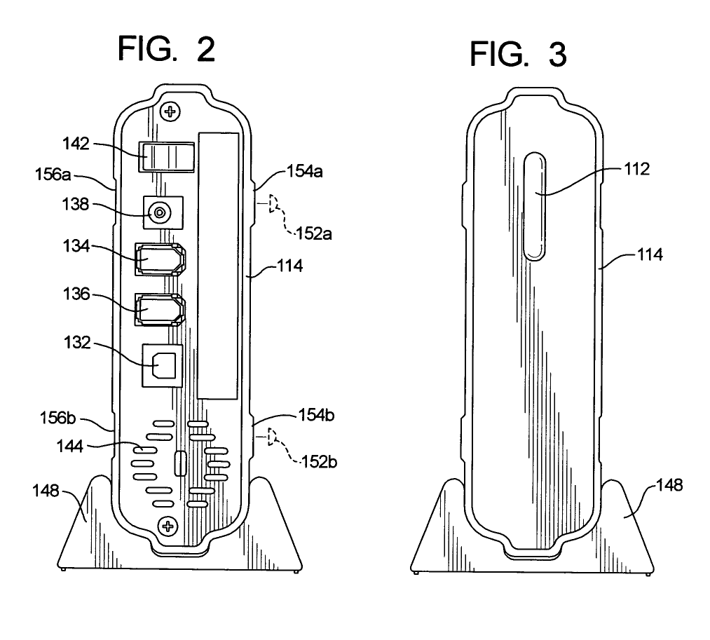

Preferably the external device 114 is configured with connectors and/or appropriate firmware, converters, and the like to accommodate any of a number of different communication channels 126. For example, in the embodiment depicted in FIG. 2, the external disk drive 114 is provided with a connector for a USB cable 132 and two IEEE 1394 (Firewire) or “i-link” cable connectors 134, 136. In some embodiments, adding two IEEE 1394 links 134, 136 allows multiple external devices to be daisy-chained together. It is also possible to connect multiple external devices via USB connections, e.g., if a USB hub is provided. FIG. 2 also depicts connections for a power supply 138 and depicts a power switch 142 as well as vent holes 144.

Although it is possible to use a number of different sizes and shapes of external data storage devices, the device depicted in FIGS. 1-7 provide a number of useful features. Preferably the external device has a relatively small size (in one embodiment, about 41 millimeters by 152 millimeters by 219 millimeters) and a relatively small weight (in one embodiment, about 1.2 kilograms). Among other advantageous aspects, a compact and lightweight external device makes it more feasible to carry the external drive with a laptop or other portable device. Because the external device has a relatively small footprint, whether positioned in a vertical configuration using an optional stand 148 as depicted in FIGS. 1-7, or lying on one of its faces, e.g., using optional adhesive feet 152a, b, the device occupies a relatively small area making it more likely to be positioned on a desktop or readily available surface, thus further encouraging regular implementation of backup or other routine or maintenance procedures. As best seen in FIG. 2, in one embodiment, opposite faces of the external device 114 are provided with (preferably nestable) ridges 154a, b and grooves 156a, b, providing relative stability when it is desired to stack two or more of the external devices 114.

In operation, a user generally will perform an installation on the host device, typically from files on a CD-ROM disk. In addition to installing drivers for the external storage device as needed 912 (FIG. 9), an installation procedure for one button functionality, as described herein, is launched 914. The one button installation can include installing a launcher program if one is not already present 916, installing backup software, if not already present, 918, and inputting or detecting the type of communication channel to be used 922. Program launchers are often provided as a part of an operating system or operating system script. For example, the MAC OS launcher is provided in certain portions of the MAC Operating System. The launcher application can be implemented as independent code, as part of the application itself, or as part of the device driver stack (e.g., a filter driver). A number of backup programs can be used in connection with the present invention. One example is DANTZ® Retrospect® backup software.

Optionally, a user may be prompted, at installation time, to configure a backup process 924, such as by selecting the drives, directories, sub-directories, files or file types which should normally be backed up, selecting a backup program or procedure, selecting a target data storage device (when more than one is available) and the like. In one embodiment, backup configuration 924 may be performed by running a configuration routine provided as part of the backup software installed in step 918.

Generally, following installation on the host device, the external device 114 is coupled to the host by an IEEE 1394 (Firewire) cable, USB cable or other communication channel, and is coupled to a power supply 138 and turned on 142. Preferably, the host device is configured and programmed such that it will recognize the connection and automatically load appropriate drivers, and perform other procedures necessary for operating in conjunction with the external device. Those with skill in the art will understand how to provide and use host device programming or operating systems to implement such procedures.

As depicted in FIG. 10, preferably each time the host device or computer is booted-up or restarted 1012, the launcher application (installed in step 916) is started (preferably running in background) 1014 with the launcher establishing connections with the external storage device through associated device drivers 1016. In embodiments or configurations where polling is used, a polling procedure may optionally be initiated 1018.

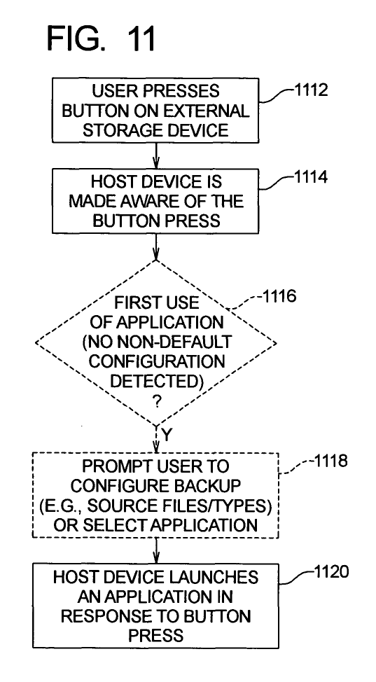

FIG. 11 provides a general overview of a procedure according to an embodiment of the present invention. In the embodiment of FIG. 11, the user presses a button 112 on the external storage device 1112. The host device is made aware of the button press 1114 through any of various means including as described herein. Optionally, the host is made aware of whether this is the first use of the one-button application 1116 (such as by determining whether a non-default configuration file for the application is detected). If this appears to be the first use, the user is prompted to configure the backup or application (e.g., as described in optional step 924) 1118. After configuring, or if configuration is not performed or is unnecessary, the host device launches an application 1120 in response to the button press.

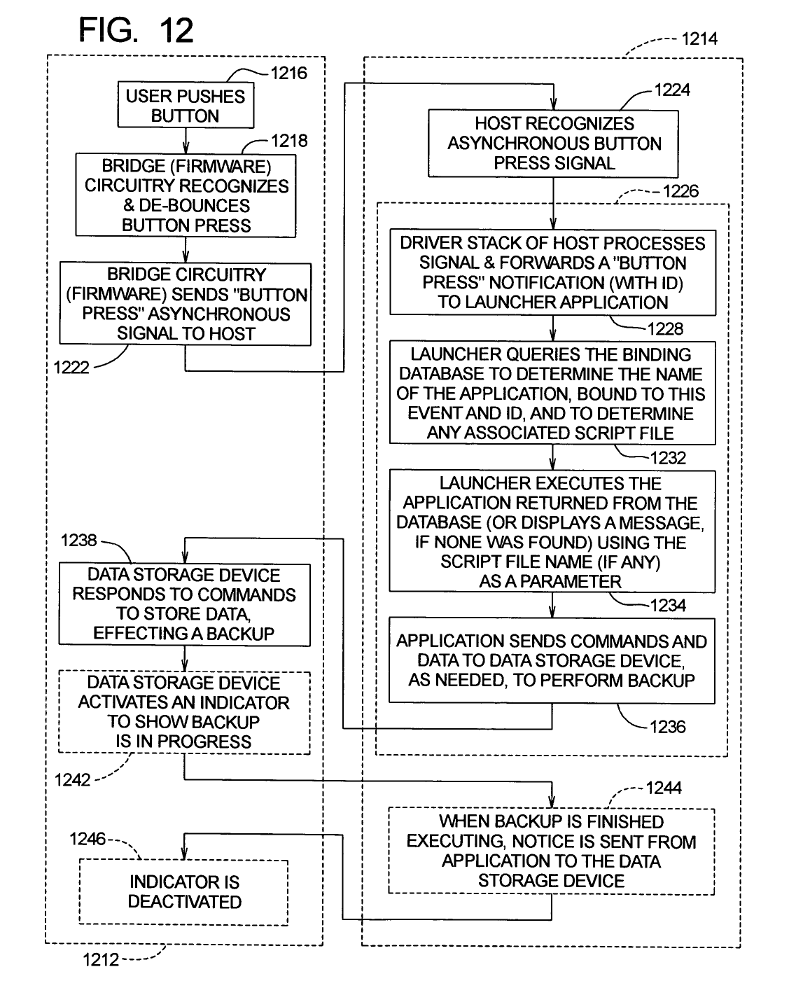

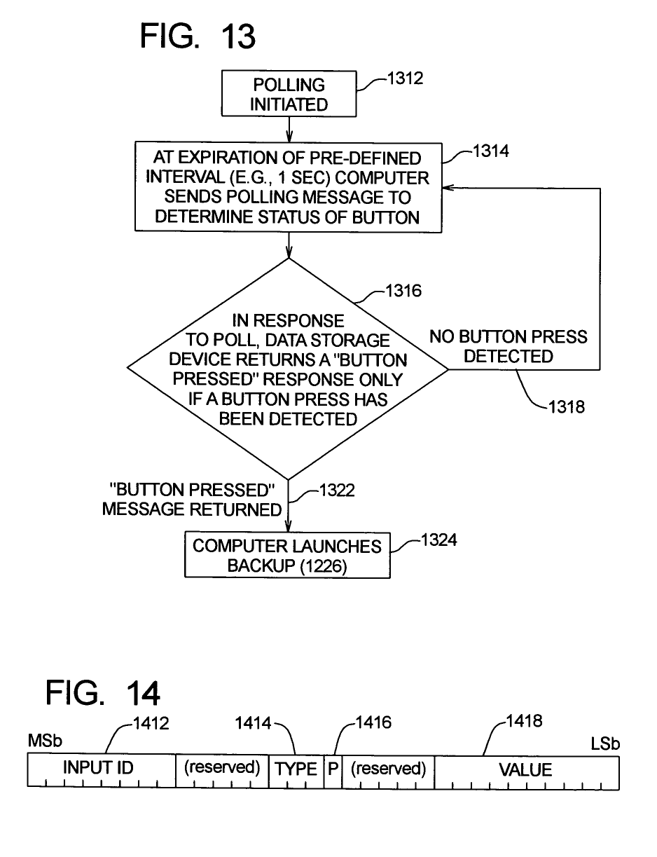

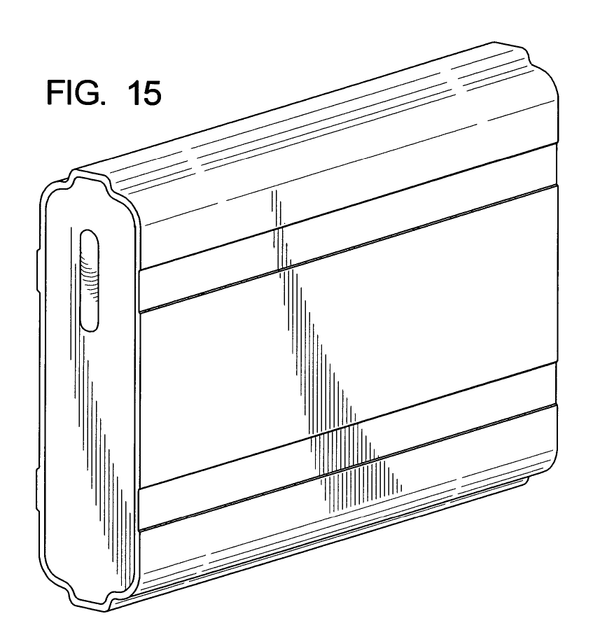

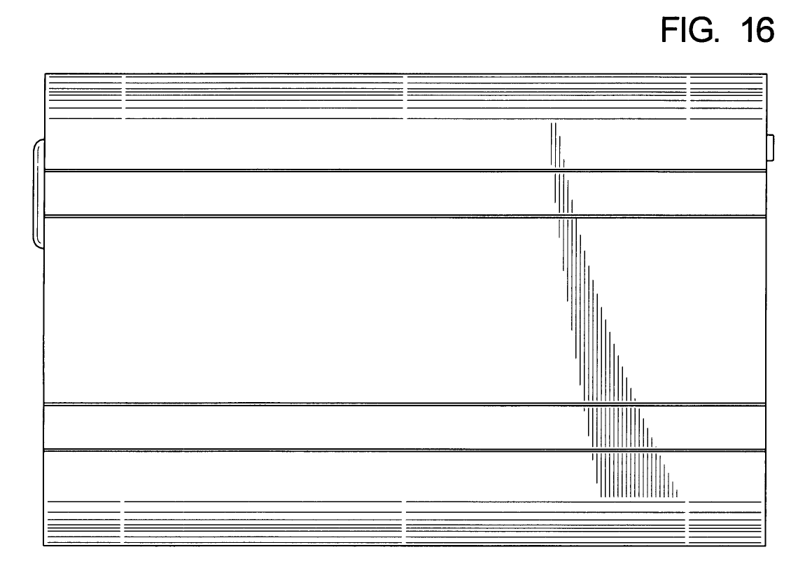

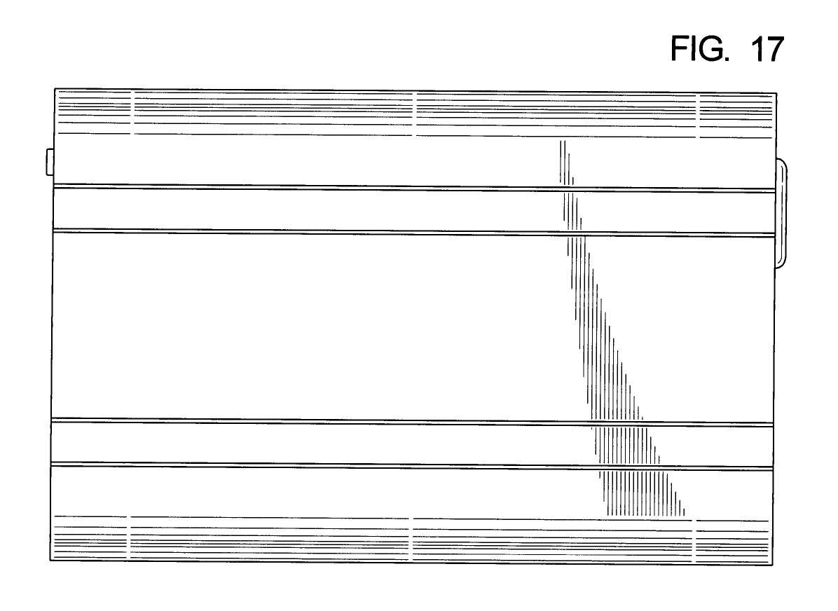

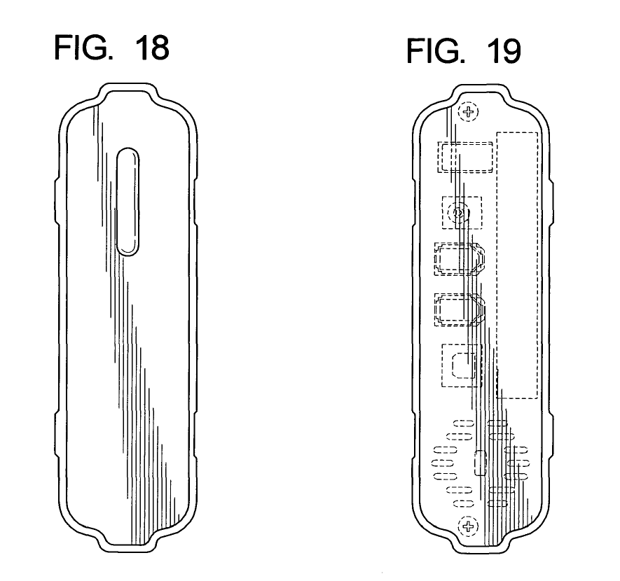

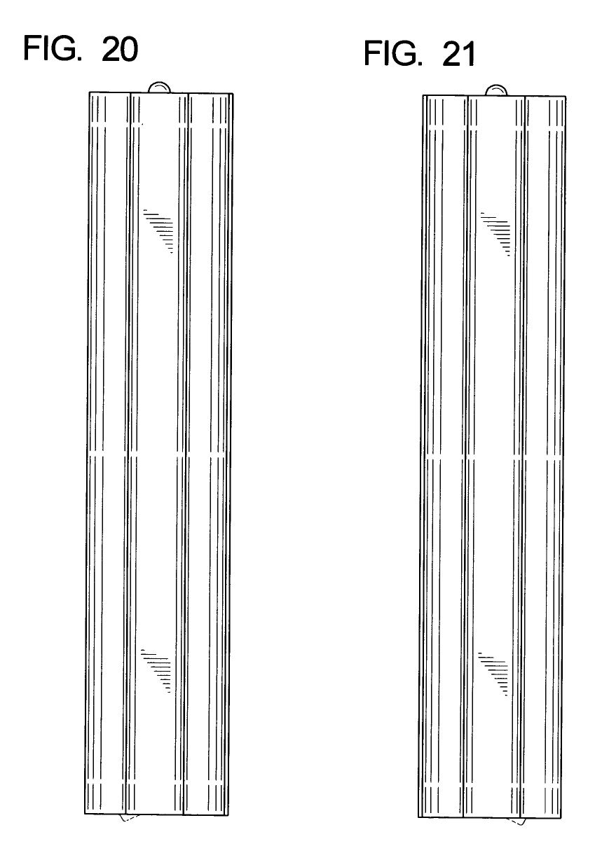

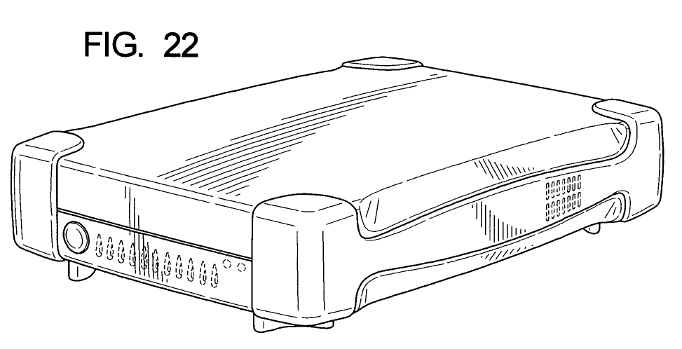

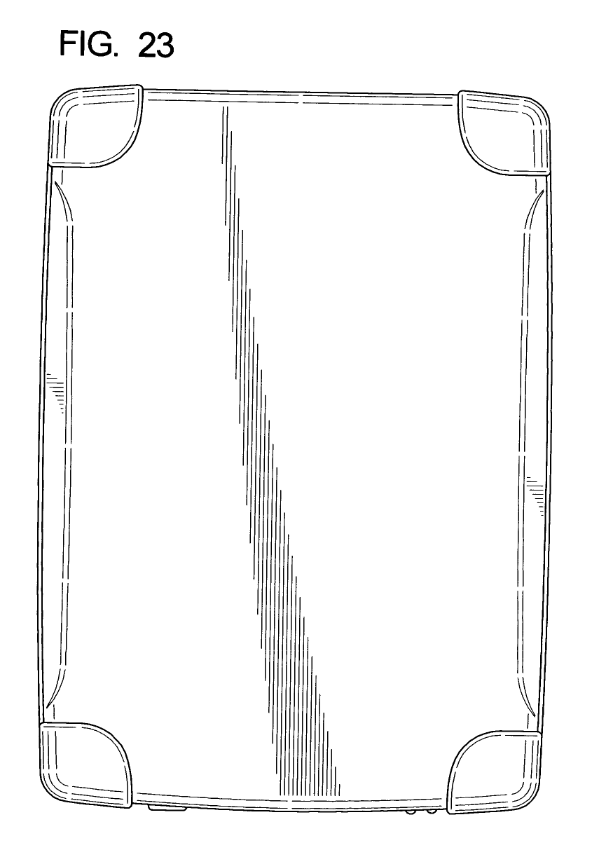

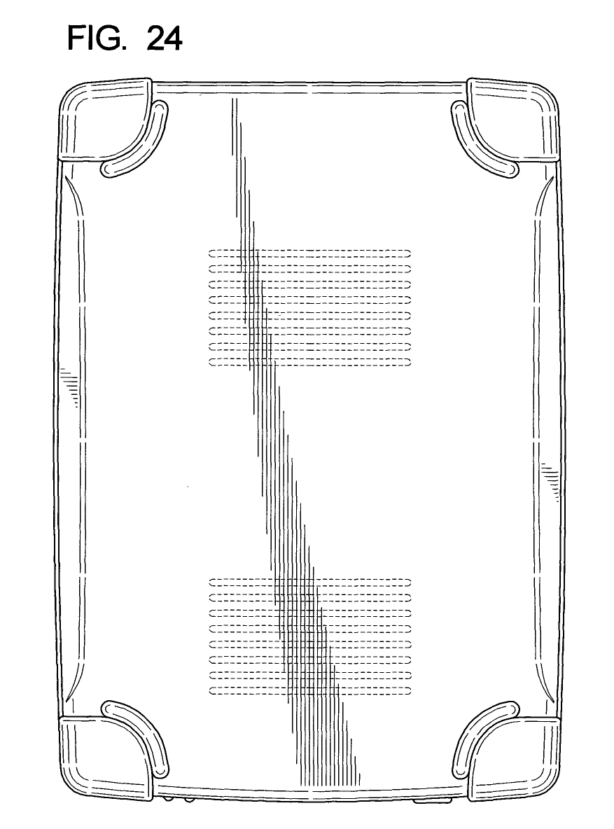

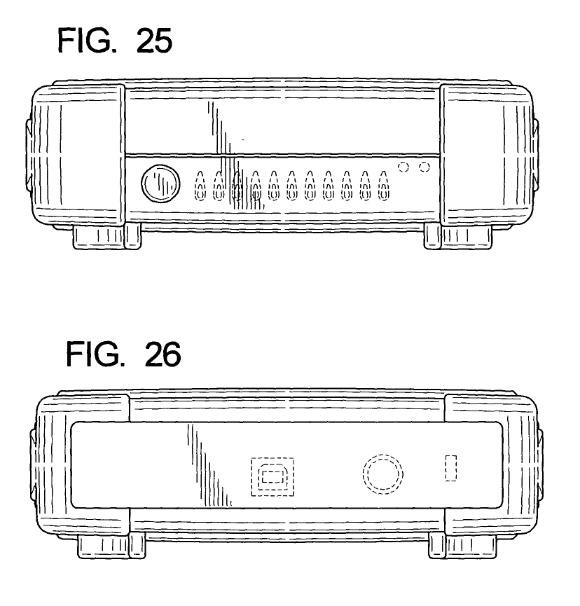

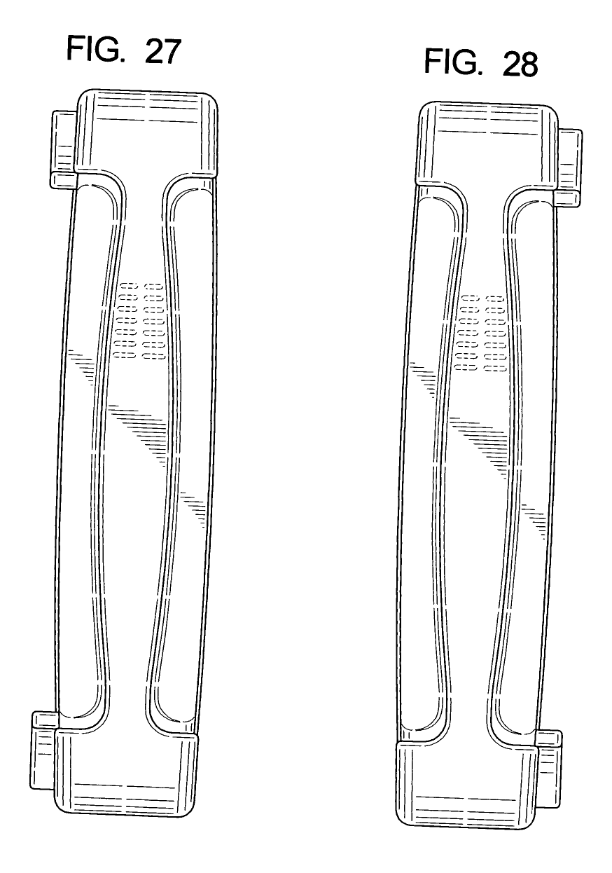

An example of an interrupt technique is described in connection with FIG. 12 and a polling technique is described in connection with FIG. 13. The choice of button event notifications may be related to the interface used to connect the external storage device to the host device. The IEEE 1394 (Firewire) bus supports both interrupt and polling button event notification methods while the USB bus generally does not allow devices to send asynchronous messages to the host device, so the polled method is used instead. Preferably, with an IEEE 1394 (Firewire) communications channel, the interrupt technique is preferred since it provides efficient and quick notice (as opposed to polling which involves a certain amount of delay associated with the polling frequency).

As will be understood by those with skill in the art, the host 124 typically includes a binding database which associates certain applications and/or files with various events and/or file types. The launcher application sends a query to the binding database. The query is used to determine the name of the application which is bound to the “button press” event and identification information 1232. The query also results in returning, to the launcher, the name of any associated script file. The script file will typically be either a default script file or will be a script file which was created or modified during a configuration procedure 924, 1118. The script file may include, e.g., information indicative of the drives, directories, sub-directories, files, file types and the like which are to be backed up. After obtaining the application name and script file name, the launcher executes the application which was returned from the binding database, typically using the script file name (if any) as a parameter 1234. If no application was found bound to the button press event, preferably a message is displayed to the user. As the application executes, it sends appropriate commands and data to the data storage device 1236 over the communication channel 126, as needed to perform the desired backup. The data storage device 114 responds to the commands and data 1238 by storing data in a manner so as to effect the desired backup.

In some embodiments, the external data storage device 114 may be provided with one or more indicators, such as LED's or other lights, LCD's or other graphical displays, sound generators and the like. In the embodiment depicted in FIG. 12, the data storage device may optionally activate an indicator 1242, e.g., to show to the user that a backup is in progress. When the backup is finished executing, notification of this fact is sent from the host device running the application to the data storage device 1244 and the indicator is deactivated 1246.

Although, as noted above, the IEEE 1394 (Firewire) bus supports both polling and interrupt methods, it is believed that no existing protocols were readily adaptable for this use. Accordingly, a button event notification protocol, generally in accordance with the description herein, can be used for this purpose if desired. In one example, such protocol supports multiple inputs and outputs such as up to 250 inputs and 250 outputs. Preferably, each input may have a plurality of values such as up to 1024 values and an indicator of whether the input is currently “pressed” or “activated.” The examples of inputs are momentary push buttons (2 states), SCSI ID selectors (8 or 16 positions) and slider switches (2 positions). Preferably, according to the protocol, the external device has a unit directory in its 1394 configuration ROM describing features and parameters. According to this protocol, devices operate using the request-response model. Such device is never an initiated transaction unless a request to do so has been received. The request initiator is the host. Requests are packaged in management operation request blocks (MORB) and sent to a panel management agent. Each MORB includes the result address where the device writes status information when the request is completed. The address of the panel management agent is the external device's unit directory. According to this protocol, the external device supports both a polled mode, where the host periodically reads the status of inputs on the device (any number of hosts can poll for input simultaneously) and also supports input notification mode in which the host registers a notification address and the external device will write data to that address whenever an input changes state. The data indicates which input was affected and its current value. Resource constraints may limit the number of hosts that can register for notifications. According to some versions of the protocol, hosts may also use a hybrid approach, registering for input notifications but reading the input's status on the device that sends the notification.

According to the protocol, an IO status block provides information about the state of the external device's inputs and outputs. The IO status block is located at an IO block address, and provides static information about the input and the input's current state. The IO status block provides the most recent information to ensure that if a host reads the IO status block after it receives an input notification, it will receive data at least as recent as the data contained in the input notification. FIG. 14 provides an example of an input information/status format of the type which can be used in accordance with the protocol. The input ID field identifies the input 1412. Each input on a device has a unique ID. Input ID's may not be numbered consecutively and the entries in the input status ready may not be in any particular order. The type field 1414 indicates the type of input such as toggle switch, slider, momentary push button and the like. The pressed bit 1416 is set if the button or switch is currently activated. For example, this bit will be set while a momentary push button is held down. The value field 1418 is the current value of the input. For non-momentary inputs, this is the state of the input. For momentary inputs (e.g., spring-loaded, push buttons), this is the number of times the button has been pressed. In the depicted configuration, the value is a ten-bit counter and, accordingly, rolls over at 1023.

According to this protocol, the front panel management agent is the means by which the host makes requests. Each request contains a function number and result address. After carrying out the requested function, the device will send result and status information back to the host at that result address.

Although a protocol generally as described herein is believed operable to implement at least some embodiments of the invention as described herein, those with skill in the art will understand how to form and use this and other potential protocols for implementing embodiments of the present invention.

As depicted in FIG. 13, embodiments of the present invention can also be provided using a polling method. After polling is initiated 1312 (e.g., when the computer is booted or restarted as shown on FIG. 10) at the expiration of each predefined interval (e.g., about once per second, in some embodiments), the host sends a polling message to the external device in order to determine the status of the button 1314. In response to the poll, the data storage device returns a “button-pressed” response if a button press has been detected 1316. The system loops 1318 through this procedure until such time as a “button-pressed” message is returned 1322, at which time the computer launches the backup application 1324 (e.g., by executing steps 1226 as depicted in FIG. 12). After launching the backup 1324, the system returns to the polling loop 1314 to 1318.

In light of the above description, a number of advantages of the present invention can be seen. Embodiments of the invention allow a simple user interface such as a single button press, to perform a routine operation, believed to be especially useful in connection with performing a backup to an external storage device. This allows the user to perform a convenient, single physical act (e.g., during or at the conclusion of a series of data update/change operations) to protect the data. The general concept can be extended to other applications besides backup and to other types of storage devices. The present invention provides a single button, which can be a single-purpose button, on an external storage device which can be configured to launch a backup (or other) application residing on a host and causing execution of the backup to occur, back to the external storage device. Embodiments of the invention involve integration of hardware (storage device, button, bridge), firmware (bridge/storage device), and software (device driver, application) to provide this feature. The present invention can reduce the number of acts or steps involved in initiating the backup, preferably requiring only a single activation of a button or other user input device. The present invention can be configured to minimize impact on ongoing computer operations such as reducing or avoiding the need for occupying display screen windows or otherwise occupying space on the display screen during, or as part of, the backup process. The present invention can provide for a backup or other action while avoiding the need to locate and/or use an ordinary mouse or keyboard. The present invention can provide for easy implementation, avoiding the need for opening a computer chassis or CPU “box” and preferably employing a communication channel, which in at least some embodiments, is “hot swappable” and has, at least in some embodiments, some “plug and play” features. The present invention avoids, at least in some embodiments, the need for consuming the computer's internal storage resources. The present invention, at least in some embodiments, makes it unlikely that a backup is cancelled or prohibited because the external storage device is unavailable or uncoupled. The present invention provides for relatively rapid writing of backup data (e.g., compared with a CD-based backup) and can avoid the need for inserting, labeling and/or locating multiple disks.

A number of variations and modifications of the invention can be used. It is possible to use some features of the invention without using others. For example, it is possible to provide for a single button external device backup without also providing for daisy-chain capability of multiple external devices. Although procedures have been described which can be used in connection with some embodiments of the invention, it is possible to implement embodiments of the invention which use procedures having more or fewer steps, which perform steps in different order or which otherwise use procedures different from those depicted and described. Although embodiments have been described in which an external drive is provided with a single button, it is believed there is no theoretical reason why embodiments could not be provided in which two or more buttons are used, e.g., for launching two or more different applications or functions, providing for button combinations and the like. For example, different buttons or types of button presses could be used to define different types of backups (such as default backup, delayed backup, background backup and the like) or for launching different (non-backup) applications. Although embodiments have been described in which a single button press suffices to launch a backup or, in some embodiments other applications, it is believed there is no theoretical reason why embodiments of the present invention could not provide for launching backup or other applications in response to two or more presses of a button. In addition to, or in place of, a described electromechanical push button, other types of user input devices could be used in connection with the present invention for launching backup or other applications, including heat-sensitive switches, membrane switches, piezoelectric switches, proximity switches, heat-sensing switches, touch screens, voice activation systems, biometric sensors, and the like. Although embodiments of the present invention have described positioning a button or other user input device substantially rigidly coupled to the chassis or the body of an external device, it is also possible to associate a button or other external or other user input device with an external storage device, including, e.g., providing a button or other user input device which is flexibly connected such as by a ribbon connector, cable or the like, providing a wireless link between a user input device and the external storage device, and the like. Although embodiments have been described in which the external data storage device includes a hard disk drive, it is believed there is no theoretical reason why embodiments of the present invention could not be implemented using other types of storage devices in place of, or in addition to, a hard disk drive including, for example, floppy disk drive, optical disk drives, flash memory, or other data storage devices presently existing or to be developed. Although embodiments have been described in which the hardware for detecting a button press is part of the bridge circuitry 128, it is also possible to provide such circuitry in the disk drive 116 itself, e.g., via device pins. This would require drive firmware to detect the button status change and initiate communication with the host, e.g., via the bridge. However, it potentially provides an opportunity to utilize a simplified bridge 128 or even to eliminate the bridge 128 altogether (such as in a small computer system interface (SCSI) drive which otherwise does not require a bridge). Although, in at least one embodiment, in response to a button press, the system will unconditionally proceed with a backup or other operation, it is also possible to provide embodiments in which, when a backup or other operation is initially launched in a response to a button press, the application allows the user to abort the backup operation. Although embodiments have been described in which a user configures backup software before the first backup operation is performed, it is also possible to provide embodiments in which no such configuration is required, e.g., such that the first time the button is pushed, even in the absence of a user configuration, the system will perform a backup, e.g., using default values, such as to provide an effective “boot disk” on the external storage device.

The present invention, in various embodiments, includes components, methods, processes, systems and/or apparatus substantially as depicted and described herein, including various embodiments, sub-combinations, and subsets thereof. Those with skill in the art will understand how to make and use the present invention after understanding the present disclosure. The present invention, and various embodiments, includes providing the devices and processes in the absence of items not depicted and/or described herein or in various embodiments hereof, including in the absence of such items as may have been used in previous devices or processes, e.g., for improving performance, achieving ease and/or reducing cost of implementation. The present invention includes items which are novel, and terminology adapted from previous and/or analogous technologies, for convenience in describing novel items or processes, do not necessarily retain all aspects of conventional usage of such terminology.

The foregoing discussion of the invention has been presented for purposes of illustration and description. The foregoing is not intended to limit the invention to the forms or form disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including ultimate, interchangeable and/or equivalent structures, functions, ranges or steps to those claimed, whether or not such ultimate, interchangeable and/or equivalent structures, functions, ranges or steps are disclosed herein, and without intending to publicly dedicate any patentable subject matter.

What is claimed is:

1. Apparatus, operatively coupled by a communications channel to a host computer, the host computer having at least a first disk drive, the apparatus comprising:
a second disk drive;
a user-activatable button associated with said second disk drive;
circuitry, operatively coupled to said second disk drive, which, in response to a press of said user-activatable button, causes a backup of at least some data from said first disk drive to said second disk drive.

2. Apparatus, as claimed in claim 1, wherein said second disk drive is an external disk drive.

3. Apparatus as claimed in claim 1, wherein said second disk drive has a housing and wherein said user-activatable button is associated with said data storage device by being mounted on said housing.

4. Apparatus as claimed in claim 1, wherein said second disk drive has a housing and wherein said housing is provided in the absence of being rigidly attached to said host computer.

5. Apparatus as claimed in claim 1, wherein said communications channel includes a communications channel selected from the group consisting of a Universal Serial Bus (USB) communications channel, an IEEE 1394 communications channel, a wireless communications channel and an Ethernet communications channel.

6. Apparatus as claimed in claim 1 further comprising an indicator which indicates execution of said backup.

7. Apparatus as claimed in claim 1 wherein, during normal use, operation of said user-activatable button suffices, substantially by itself, to initiate said backup, in the absence of a need for user input other than said operation of said user-activatable button.

8. Apparatus, as claimed in claim 1 wherein, prior to normal operation of said apparatus for backup, said host computer can be provided with configuration information relating to said backup.

9. A data storage apparatus, operatively coupled to a host device, comprising:
a housing containing a data storage device and circuitry for controlling said data storage device to write data, sent from said host device, onto said data storage device and to read data for sending to said host device, said housing being external to said host device wherein said housing is provided in the absence of being rigidly attached to said host device;
a communications channel for accommodating the sending of data to and from said host device;
at least a first user input device associated with said data storage apparatus; circuitry, coupled to said data storage device, which, in response to at least a first input provided on said user input device, performs at least one of:
a user-selectable function performed at least partially on said host device; and
substantially automatic storage of data sent from said host device to said data storage device.

10. Apparatus as claimed in claim 9, wherein said user input device is associated with said data storage device by being mounted on said housing.

11. Apparatus as claimed in claim 9, wherein said host device is a computer.

12. Apparatus as claimed in claim 11, wherein said computer includes at least a first internal data storage device.

13. Apparatus as claimed in claim 12, wherein said internal data storage device is a hard disk drive.

14. Apparatus as claimed in claim 11, wherein said substantially automatic storage of data comprises a back up of at least part of the totality of data stored in said computer.

15. Apparatus as claimed in claim 11, wherein said substantially automatic storage of data comprises a backup of predetermined portions of data stored in said computer.

16. Apparatus as claimed in claim 11, wherein said substantially automatic storage of data comprises a backup of user-selectable portions or types of data stored in said computer.

17. Apparatus as claimed in claim 9, wherein said data storage apparatus comprises a disk drive.

18. Apparatus as claimed in claim 9, wherein said communications channel includes a communications channel selected from the group consisting of a Universal Serial Bus (USB) communications channel, an IEEE 1394 communications channel, a wireless communications channel and an Ethernet communications channel.

19. Apparatus as claimed in claim 9, wherein said user input device comprises a pressable button.

20. Apparatus as claimed in claim 9 further comprising an indicator which indicates execution of said at least one of a user-selectable function and substantially automatic storage.

21. Apparatus as claimed in claim 9 wherein, during normal use, operation of said user input device suffices, substantially by itself, to initiate execution of said at least one of a user-selectable function and substantially automatic storage, in the absence of a need for user input other than said operation of said user input device.

22. Apparatus, as claimed in claim 21, wherein, prior to normal operation of said apparatus for backup, said host device can be provided with configuration information relating to said at least one of a user-selectable function and substantially automatic storage.

23. A method for use in connection with a data storage device, operatively coupled to a host device, comprising:
providing a housing which contains said data storage device said housing being external to said host device wherein said housing is provided in the absence of being rigidly attached to said host device;
electronically controlling said data storage device to write data, sent from said host device, onto said data storage device and to read data for sending to said host device over a communications channel;
providing input via a user input device associated with said data storage device;
performing, in response to at least a first input provided on said user input device, at least one of:
a user-selectable function wherein said function is performed at least partially on said host device; and
substantially automatic storing of data sent from said host device to said data storage device.

24. A method as claimed in claim 23, wherein said user input device is associated with said data storage device by being mounted on said housing.

25. A method as claimed in claim 23, wherein said host device is a computer.

26. A method as claimed in claim 25, wherein said computer includes at least a first internal data storage device.

27. A method as claimed in claim 26, wherein said internal data storage device is a hard disk drive.

28. A method as claimed in claim 25, wherein said substantially automatic storing of data comprises performing a back up of at least part of the totality of data stored in said computer.

29. A method as claimed in claim 25, wherein said substantially automatic storing of data comprises performing a backup of predetermined portions of data stored in said computer.

30. A method as claimed in claim 25, wherein said substantially automatic storing of data comprises performing a backup of user-selectable portions or types of data stored in said computer.

31. A method as claimed in claim 23, wherein said data storage device comprises a disk drive.

32. A method as claimed in claim 23, wherein said communications channel includes a communications channel selected from the group consisting of a Universal Serial Bus (USB) communications channel, an IEEE 1394 communications channel, a wireless communications channel and an Ethernet communication channel.

33. A method as claimed in claim 23, wherein said user input device comprises a pressable button and wherein said step of providing input comprises pressing said pressable button.

34. A method as claimed in claim 23 further comprising providing an indication of the execution of said at least one of a user-selectable function and substantially automatic storage.

35. A method as claimed in claim 23 wherein, during normal use, operation of said user input device suffices, substantially by itself, to initiate execution of said at least one of a user-selectable function and substantially automatic storage, in the absence of a need for user input other than said operation of said user input device.

36. Apparatus for use in connection with a data storage device, operatively coupled to a host device, comprising:
a housing means for containing said data storage device said housing means being external to said host device wherein said housing means is provided in the absence of being rigidly attached to said host device;
means for controlling said data storage device to write data, sent from said host device, onto said data storage device and to read data for sending to said host device over a communications means;
a user input means, associated with said data storage apparatus;
means for performing, in response to at least a first input provided on said user input means, at least one of:
a user-selectable function wherein said function is performed at least partially on said host device; and
substantially automatic storage of data sent from said host device to said data storage device.

37. Apparatus as claimed in claim 36, wherein said user input means is associated with said data storage device by being mounted on said housing.

38. Apparatus as claimed in claim 36, wherein said host device is a computer.

39. Apparatus as claimed in claim 38, wherein said computer includes at least a first internal data storage means.

40. Apparatus as claimed in claim 39, wherein said internal data storage means is a hard disk drive.

41. Apparatus as claimed in claim 38, wherein said means for performing substantially automatic storage of data comprises means for performing a backup of at least part of the totality of data stored in said computer.

42. Apparatus as claimed in claim 38, wherein said means for performing substantially automatic storage of data comprises means for performing a backup of predetermined portions of data stored in said computer.

43. Apparatus as claimed in claim 38, wherein said means for performing substantially automatic storage of data comprises means for performing a backup of user-selectable portions or types of data stored in said computer.

44. Apparatus as claimed in claim 36, wherein said data storage device comprises a disk drive.

45. Apparatus as claimed in claim 36, wherein said communications means includes a communications channel selected from the group consisting of a Universal Serial Bus (USB) communications channel, an IEEE 1394 communications channel, a wireless communications channel and an Ethernet communications channel.

46. Apparatus as claimed in claim 45, wherein said user input means comprises a pressable button.

47. Apparatus as claimed in claim 36 further comprising means for providing an indication of the execution of said at least one of a user-selectable function and substantially automatic storage.

48. Apparatus as claimed in claim 36 wherein, during normal use, operation of said user input means suffices, substantially by itself, to initiate execution of said at least one of a user-selectable function and substantially automatic storage, in the absence of a need for user input other than said operation of said user input device.

49. Apparatus, as claimed in claim 48, further comprising means for communicating to said host device, configuration information relating to said at least one of a user-selectable function and substantially automatic storage, prior to normal use of said data storage device for backup.

50. Apparatus for data backup, operatively coupled to a host computer, comprising:
a disk drive;
a housing containing said disk drive, said housing and disk drive being external to said host computer wherein said housing is provided in the absence of being rigidly attached to said host device;
circuitry which controls said disk drive to write data, sent from said host computer, onto said disk drive and to read data for sending to said host computer over a communications channel;
a push button mounted on said housing;
circuitry configured to perform a backup of at least selected data stored in said computer, onto said disk drive, in response to activation of said push button.

51. Apparatus as claimed in claim 50, wherein said circuitry configured to perform a backup comprises circuitry configured to perform a backup of predetermined portions of data stored in said computer.

52. Apparatus as claimed in claim 50, wherein said circuitry configured to perform a backup comprises circuitry configured to perform a backup of user-selectable portions or types of data stored in said computer.

53. Apparatus as claimed in claim 50, wherein said communications channel is selected from the group consisting of a Universal Serial Bus (USB) communications channel, an IEEE 1394 communications channel, a wireless communications channel and an Ethernet communications channel.

54. Apparatus as claimed in claim 50 further comprising an indicator which indicates initiation, progress or completion of said backup.

55. Apparatus as claimed in claim 50 wherein, during normal use, operation of said button suffices, substantially by itself, to initiate execution of said backup, in the absence of a need for user input other than said operation of said button.

56. Apparatus, as claimed in claim 51, wherein configuration information relating to said backup is performed prior to normal use of said disk drive for backup.

57. A method for data backup, operatively coupled to a host computer, comprising:
mounting a disk drive in a housing, said housing and disk drive being external to said host computer wherein said housing is provided in the absence of being rigidly attached to said host device;
controlling said disk drive to write data, sent from said host computer, onto said disk drive and to read data for sending to said host computer over a communications channel;
mounting a push button on said housing, operatively connected, at least indirectly, to said disk drive;
performing a backup of at least selected data stored in said computer, onto said disk drive, in response to activation of said push button.

58. A method as claimed in claim 57, wherein said step of performing a backup comprises performing a backup of predetermined portions of data stored in said computer.

59. A method as claimed in claim 57, wherein said step of performing a backup comprises performing a backup of user-selectable portions or types of data stored in said computer.

60. A method as claimed in claim 57, wherein said communications channel is selected from the group consisting of a Universal Serial Bus (USB) communications channel, an IEEE 1394 communications channel, a wireless communications channel and an Ethernet communications channel.

61. A method as claimed in claim 57 further comprising indicating initiation, progress or completion of said backup.

62. A method as claimed in claim 57 wherein, during normal use, operation of said button suffices, substantially by itself, to initiate execution of said backup, in the absence of a need for user input other than said operation of said button.

63. A method, as claimed in claim 57, further comprising providing configuration information relating to said backup, prior to normal use of said disk drive for backup.

64. A method, as claimed in claim 63, wherein said configuration information includes identification of drives, directories, sub-directories, files or file types designated for backup.

65. A method, as claimed in claim 63, wherein said configuration information includes designation of a backup destination.

66. Apparatus for data backup, operatively coupled to a host computer, comprising:
means for mounting a disk drive in a housing means, said housing means and disk drive being external to said host computer wherein said housing means is provided in the absence of being rigidly attached to said host device;
means for controlling said disk drive to write data, sent from said host computer, onto said disk drive and to read data for sending to said host computer over a communications means;
button means on said housing, operatively connected, at least indirectly, to said disk drive;
means for performing a backup of at least selected data stored in said computer, onto said disk drive, in response to activation of said button means.

67. Apparatus as claimed in claim 66, wherein said means for performing a backup comprises means for performing a backup of predetermined portions of data stored in said computer.

68. Apparatus as claimed in claim 66, wherein said means for performing a backup comprises means for performing a backup of user-selectable portions or types of data stored in said computer.

69. Apparatus as claimed in claim 66, wherein said communications channel is selected from the group consisting of a Universal Serial Bus (USB) communications channel, an IEEE 1394 communications channel, a wireless communications channel and an Ethernet communications channel.

70. Apparatus as claimed in claim 66 further comprising means for indicating at least one of initiation, progress or completion of said backup.

71. Apparatus as claimed in claim 66 wherein, during normal use, operation of said button means suffices, substantially by itself, to initiate execution of said backup, in the absence of a need for user input other than said operation of said button means.

72. Apparatus, as claimed in claim 66, further comprising means for providing configuration information relating to said backup, prior to normal use of said disk drive for backup.

73. Apparatus, as claimed in claim 72, wherein said configuration information includes identification of drives, directories, sub-directories, files or file types designated for backup.

74. Apparatus, as claimed in claim 72, wherein said configuration information includes designation of a backup destination.

75. Apparatus for data backup, operatively coupled to a host computer, comprising:
a disk drive;
a housing containing said disk drive;
circuitry which controls said disk drive to write data, sent from said host computer, onto said disk drive;
a push button operatively coupled to said housing;
circuitry configured to receive an indication of a status of said button and to pass said button status information to said host computer;
said host computer configured to respond to at least a first button status, or status change, by executing software which is configured to store at least first information in said host computer onto said disk drive.

76. Apparatus as claimed in claim 75, wherein said housing is provided in the absence of being rigidly attached to said host device.

77. Apparatus, as claimed in claim 75, wherein said disk drive is coupled to bridge circuitry which provided for serial-to-parallel data conversion and wherein said circuitry configured to receive an indication of a status of said button is provided on said bridge circuitry.

78. Apparatus, as claimed in claim 75, wherein said disk drive is coupled to drive control circuitry which includes control of an actuator arm of said disk drive and wherein said circuitry configured to receive an indication of a status of said button is provided on said drive control circuitry.

79. Apparatus as claimed in claim 75, wherein said host computer configured to respond to at least a first button status by periodically polling to determine button status.

80. Apparatus as claimed in claim 75, wherein said host computer is configured to respond to at least a first button status by receiving an asynchronous message from said circuitry configured to receive an indication of a status of said button.

81. Apparatus as claimed in claim 75, wherein said software includes software for passing a button notification to a launcher application.

82. Apparatus as claimed in claim 75, wherein said software includes software for querying a binder database to determine at least one of a backup application name and a backup script name.

83. Apparatus as claimed in claim 82, wherein said software includes software for executing said backup application, using said script name as a parameter.

84. A method for data backup, of data on a host computer, comprising:
providing a housing containing a disk drive;
operatively coupling a push button to said housing;
receiving an indication of a status of said button;
passing said button status information to said host computer;
said host computer responding to at least a first button status, or status change, by executing software which is configured to store at least first information in said host computer onto said disk drive.

85. A method as claimed in claim 84, wherein said housing is provided in the absence of being rigidly attached to said host device.

86. A method, as claimed in claim 84, wherein said disk drive is coupled to bridge circuitry which provides for serial-to-parallel data conversion and wherein said step of receiving an indication of a status of said button is performed using said bridge circuitry.

87. A method, as claimed in claim 85, wherein said disk drive is coupled to drive control circuitry which controls said disk drive to write data, sent from said host computer, onto said disk drive; and wherein said step of receiving an indication of a status of said button is performed using said drive control circuitry.

88. A method as claimed in claim 85 further comprising said host computer periodically polling to determine button status.

89. A method as claimed in claim 85 further comprising said host computer receiving an asynchronous message from said circuitry configured to receive an indication of a status of said button.

90. A method as claimed in claim 85, wherein said software provides for a process that includes passing a button notification to a launcher application.

91. A method as claimed in claim 85, wherein said software provides for a process that includes querying a binder database to determine at least one of a backup application name and a backup script name.

92. A method as claimed in claim 91, wherein said software provides for a process that includes executing said backup application, using said script name as a parameter.

93. Apparatus for backup of data on a host computer, comprising:
a housing containing a disk drive;
button means operatively coupled to said housing;
means for receiving an indication of a status of said button;
means for passing said button status information to said host computer;
means, on said host computer, for responding to at least a first button status, or status change, by executing software which is configured to store at least first information in said host computer onto said disk drive.

94. Apparatus as claimed in claim 93, wherein said housing is provided in the absence of being rigidly attached to said host device.

95. Apparatus, as claimed in claim 93, wherein said disk drive is coupled to bridge circuitry which provides for serial-to-parallel data conversion and wherein said means for receiving an indication of a status of said button includes said bridge circuitry.

96. Apparatus, as claimed in claim 93, wherein said disk drive is coupled to drive control circuitry which controls said disk drive to write data, sent from said host computer, onto said disk drive; and wherein said means for receiving an indication of a status of said button includes said drive control circuitry.

97. Apparatus as claimed in claim 93 further comprising means, in said host computer, for periodically polling to determine button status.

98. Apparatus as claimed in claim 93 further comprising means, in said host computer, for receiving an asynchronous message from said circuitry configured to receive an indication of a status of said button.

99. Apparatus as claimed in claim 93, wherein said software includes means for passing a button notification to a launcher application.

100. Apparatus as claimed in claim 94, wherein said software includes means for querying a binder database to determine at least one of a backup application name and a backup script name.

101. Apparatus as claimed in claim 100, wherein said software includes means for executing said backup application, using said script name as a parameter.
